(19) United States
(12) Patent Application Publication
(10) Pub. No.: US 2025/0239530 A1
(43) Pub. Date: Jul. 24, 2025

(54) ELECTRONIC PACKAGE AND MANUFACTURING METHOD OF ELECTRONIC PACKAGE

(71) Applicant: VIA Technologies, Inc., New Taipei City (TW)

(72) Inventor: Yeh-Chi Hsu, New Taipei City (TW)

(73) Assignee: VIA Technologies, Inc., New Taipei City (TW)

(21) Appl. No.: 18/634,977

(22) Filed: Apr. 14, 2024

(30) Foreign Application Priority Data
Jan. 22, 2024 (TW) 113102458

(51) Int. Cl. H01L 23/538; H01L 21/48; H01L 21/768; H01L 23/00; H01L 23/498; H01L 23/528; H01L 25/00; H01L 25/065; H01L 25/10

(52) U.S. Cl. CPC H01L 23/5385; H01L 21/4857; H01L 21/768; H01L 23/49816; H01L 23/5286; H01L 24/08; H01L 24/19; H01L 24/20; H01L 25/0655; H01L 25/105; H01L 25/50; H01L 24/16; H01L 2224/08225; H01L 2224/16225; H01L 2224/19; H01L 2224/21

(57) ABSTRACT

An electronic package includes a sub-package. The sub-package includes multiple chips, a first redistribution wiring structure, and a second redistribution wiring structure. The chips are arranged on a plane. Each of the chips has a chip substrate, multiple buried power rails, and multiple chip pads. The backside of the chip is a portion of the chip substrate correspondingly. The buried power rails are disposed penetratingly on the chip substrate, and the chip pads are disposed on active surfaces of the chips correspondingly. The first redistribution wiring structure is disposed on the active surfaces of the chips and electrically connected to the chip pads. The second redistribution wiring structure is disposed on the backside of the chips and connected to the buried power rails. The buried power rails of the chips are electrically connected to an external power supply via the second redistribution wiring structure.

### CROSS-REFERENCE TO RELATED APPLICATION

This application claims the priority benefit of Taiwan application serial no. 113102458, filed on Jan. 22, 2024. The entirety of the above-mentioned patent application is hereby incorporated by reference herein and made a part of this specification.

### BACKGROUND

### Technical Field

The disclosure relates to an electronic component, and particularly relates to an electronic package and a manufacturing method of the electronic package.

### Description of Related Art

At present, the power of the chip may be provided by the active surface or the backside of the chip. When the power is provided by the active surface of the chip, the power line transmitting the power needs to pass through the multi-layers of interconnects and vias, causing the power path to be too long, and the energy consumption is increased. In addition, when the power is provided by the backside of the chip, a nano-through-silicon via (nano-TSV) with a high aspect ratio needs to be manufactured on the backside of the chip to connect to the buried power rail and the power line of the backside of the chip. However, the aperture of the nano-through-silicon via is larger than the aperture of the buried power rail, which makes the connection between the buried power rail and the nano-through-silicon via incomplete, so that the impedance of the power line is increased, thereby the energy consumption of the chip is increased.

### SUMMARY

The disclosure provides an electronic package, used to reduce energy consumption.

The disclosure provides a manufacturing method of an electronic package, used to produce the electronic package.

In an embodiment of the disclosure, an electronic package includes a sub-package. The sub-package includes multiple chips, a first redistribution wiring structure, and a second redistribution wiring structure. The chips are arranged on a plane. Each of the chips has a chip substrate, multiple buried power rails, and multiple chip pads. The backside of the chip is a portion of the chip substrate correspondingly. The buried power rails are disposed penetratingly on the chip substrate, and the chip pads are disposed on active surface of the chips correspondingly. The first redistribution wiring structure is disposed on the active surfaces of the chips and electrically connected to the chip pads. The second redistribution wiring structure is disposed on the backside of the chips and connected to the buried power rails. The buried power rails of the chips are electrically connected to an external power supply via the second redistribution wiring structure.

In an embodiment of the disclosure, a manufacturing method of an electronic package includes the following steps. A first redistribution wiring structure is formed on a supportive carrying plate. Multiple chips are installed on the first redistribution wiring structure. The active surface of the chips are connected to the first redistribution wiring structure. A second redistribution wiring structure is formed on the backside of the chips. The second redistribution wiring structure is connected to multiple buried power rails of the chips.

Based on the above, in the disclosure, the second redistribution wiring structure is directly connected to the buried power rails of the multiple chips, so that the multiple chips of the electronic package can be directly connected to the external power supply through the second redistribution wiring structure, which facilitates improving the performance of the chips. In addition, through connecting the buried power rail of the chip directly to the second redistribution wiring structure, the process of manufacturing the nano-through-silicon via can be omitted, so as to reduce the production cost of the chip.

### BRIEF DESCRIPTION OF THE DRAWINGS

FIG. 1 is a schematic diagram of a chip of an electronic package according to an embodiment of the disclosure.

FIG. 2 is a schematic diagram of an electronic package according to an embodiment of the disclosure.

FIG. 3 is a schematic diagram of the electronic package according to another embodiment of the disclosure.

FIG. 4 is a schematic diagram of the electronic package according to still another embodiment of the disclosure.

FIGS. 5A to 5F illustrate a manufacturing method of an electronic package according to an embodiment of the disclosure.

FIGS. 6A to 6I illustrate the manufacturing method of the electronic package according to another embodiment of the disclosure.

FIGS. 7A to 7C illustrate several alternative steps of the embodiment of FIGS. 5B to 5C.

FIG. 8 is a partial schematic diagram of a power plane according to an embodiment of the disclosure.

### DESCRIPTION OF THE EMBODIMENTS

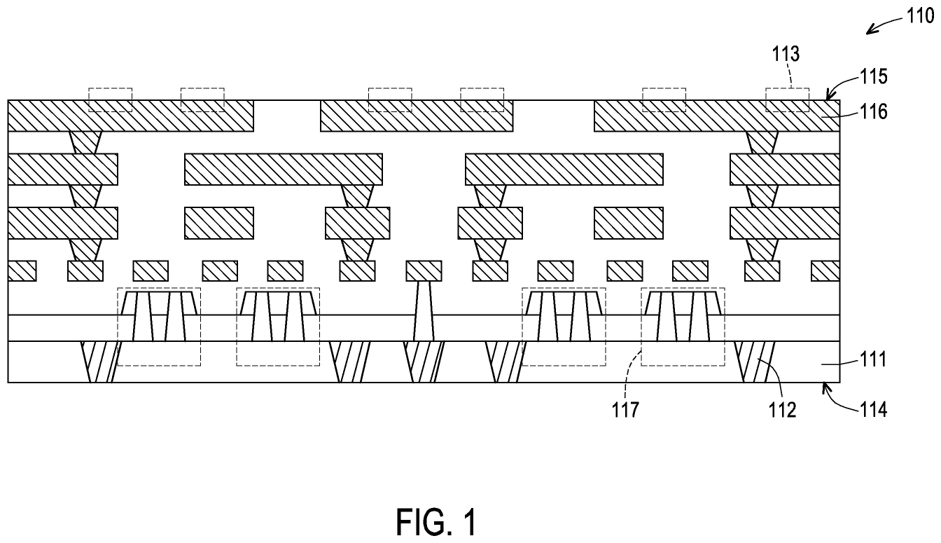

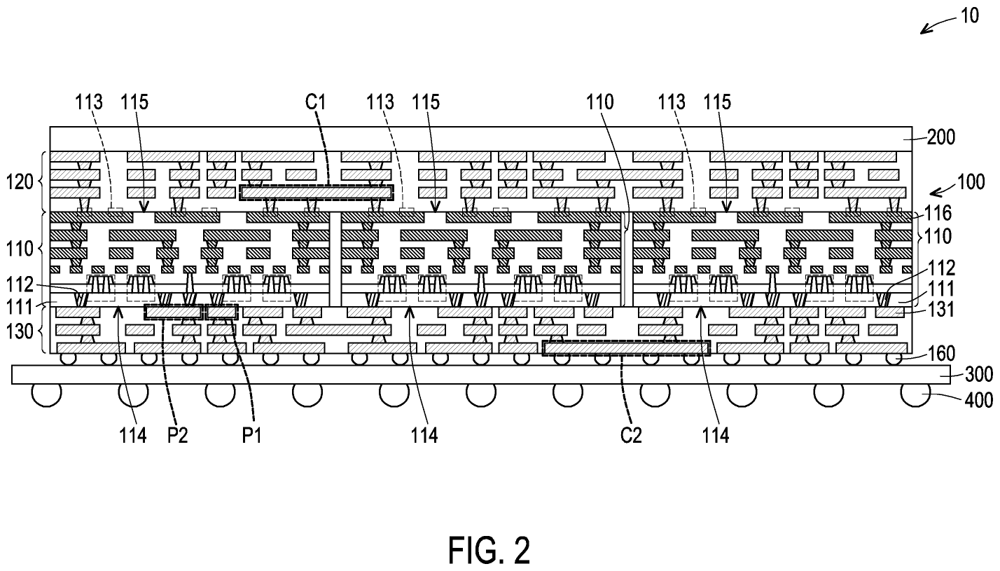

Please refer to FIG. 1 and FIG. 2. In this embodiment, an electronic package 10 includes a sub-package 100. The sub-package 100 includes a plurality of chips 110, a first redistribution wiring structure 120, and a second redistribution wiring structure 130. The chips 110 are arranged on a plane. Each of the chips 110 has a chip substrate 111, a plurality of buried power rails 112, and a plurality of chip pads 113. The backside 114 of the chip 110 is a portion of the chip substrate 111 correspondingly. The buried power rails 112 are disposed penetratingly in the chip substrate 111 and, for example, extend into the page. The chip pads 113 are disposed on an active surface 115 of the chip 110 correspondingly. The first redistribution wiring structure 120 is disposed on the active surfaces 115 of the chips 110 and electrically connected to the chip pads 113. The second redistribution wiring structure 130 is disposed on the backside 114 of the chips 110 and connected to the buried power rails 112. The buried power rails 112 of the chips 110 are electrically connected to an external power supply (not shown) via the second redistribution wiring structure 130.

Each of the chips 110 further has an internal metal bonding wire 116 and a plurality of transistors 117. Part of the internal metal bonding wire 116 forms the chip pads 113 on the active surface 115. The transistors 117 are disposed on the chip substrate 111. The transistors 117 physically or electrically connect to the internal metal bonding wire 116 and the buried power rails 112. Specifically, the transistors 117 connect to the first redistribution wiring structure 120 through the internal metal bonding wire 116, and the transistors 117 connect to the second redistribution wiring structure 130 through the buried power rails 112. In an embodiment, part of the conductive structure in the first redistribution wiring structure 120 may electrically or physically connect to at least two chips 110 to transmit signals between multiple chips 110, as shown in the area C1 marked in FIG. 2. In addition, in some embodiments, part of the conductive structure in the second redistribution wiring structure 130 may electrically or physically connect to at least two chips 110 to transmit signals between multiple chips 110, as shown in an area C2 marked in FIG. 2. In other words, though being disposed independently of each other, the chips 110 may be electrically connected through the first redistribution wiring structure 120 or the second redistribution wiring structure 130.

In this embodiment, the second redistribution wiring structure 130 further has multiple power planes 131. The power planes 131 are disposed closely to the end of the backside 114 of the chips 110, and each of the power planes 131 is directly connected to at least one of the buried power rails 112. That is to say, the quantity of connections between each of the power planes 131 and the buried power rails 112 may be one or more, depending on the needs, for example, as shown in areas P1 and P2 marked in FIG. 2. In addition, the power planes 131 are directly connected to the buried power rails 112, so that each of the chips 110 is directly connected to the external power supply through the second redistribution wiring structure 130, thereby the manufacturing of the nano-through-silicon via with a high aspect ratio on the backside 114 of the chips 110 can be omitted.

The sub-package 100 further includes multiple conductive bumps 160. The conductive bumps 160 are disposed on the second redistribution wiring structure 130 and away from the end of the power plane 131. The electronic packaging structure 10 further includes a supportive carrying plate 200, a wire carrying plate 300, and a plurality of conductive balls 400. The supportive carrying plate 200 and the first redistribution wiring structure are stacked with each other. The sub-package 100 is installed on the wire carrying plate 300 through the conductive bumps 160, and connects the plurality of conductive balls 400 to the wire carrying plate 300.

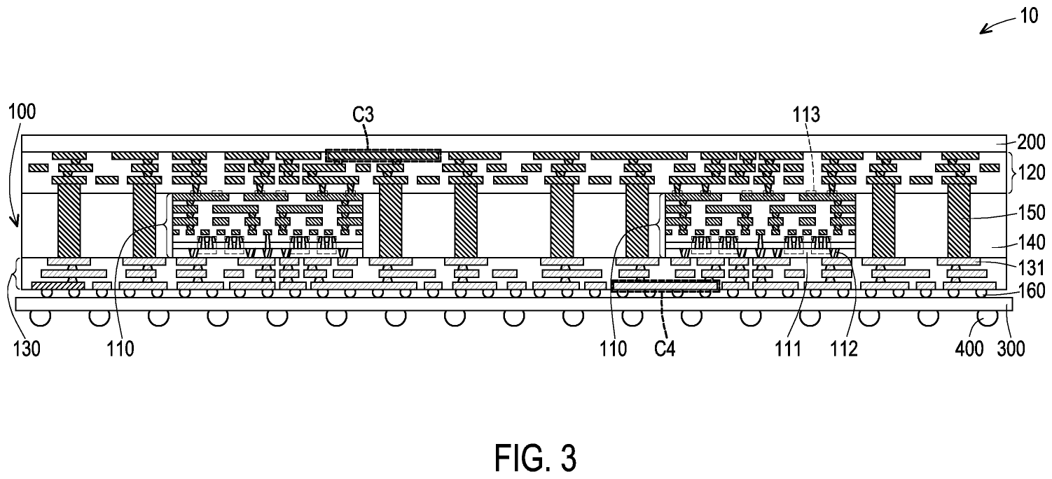

The embodiment in FIG. 3 is approximately the same as the embodiment in FIG. 2, but the difference lies in the two embodiments is that, in the embodiment in FIG. 3, the sub-package 100 further includes a dielectric layer 140. The dielectric layer 140 covers the chips 110 and exposes the multiple chip pads 113 and the multiple buried power rails 112, and the dielectric layer 140 fills a gap between two adjacent chips 110.

Please continue to refer to FIG. 3. In this embodiment, the sub-package 100 further has multiple conductive columns 150. The conductive columns 150 penetrate the dielectric layer 140 and connect to the first redistribution wiring structure 120 and the second redistribution wiring structure 130. In other words, the chips 110 are disposed between the conductive columns 150 and covered by the dielectric layer 140, and the first redistribution wiring structure 120 is electrically connected to the second circuit structure 130 through the conductive columns 150. Similarly, although the chips 110 are disposed independently of each other, part of the conductive structure in the first redistribution wiring structure 120 may electrically or physically connect to at least two chips 110, for transmitting signals between the multiple chips 110, as shown in the area C3 marked in FIG. 3. Part of the conductive structure in the second redistribution wiring structure 130 may electrically or physically connect to at least two chips 110, for transmitting signals between the multiple chips 110, as shown in the area C4 marked in FIG. 3.

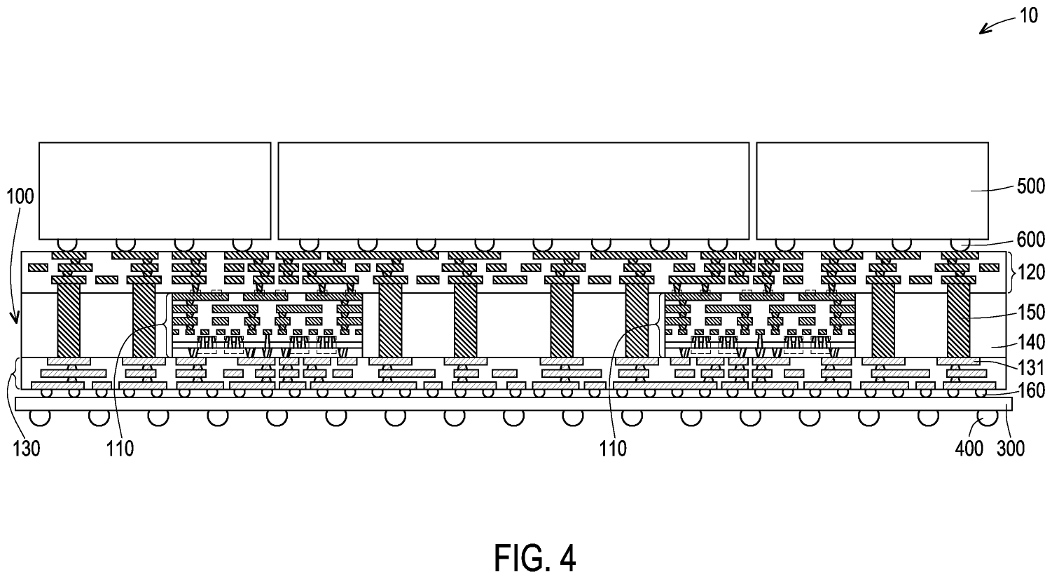

The embodiment in FIG. 4 is approximately the same as the embodiment in FIG. 3, but the difference lies in the two embodiments is that, in the embodiment in FIG. 4, the electronic package 10 further includes multiple electronic components 500, and the electronic components 500 may be installed on the first redistribution wiring structure 120 through multiple conductive balls 600. Specifically, before installing the electronic component 500 on the first redistribution wiring structure 120, the supportive carrying plate 200 is removed. That is to say, the electronic components 500 are electrically connected to the first redistribution wiring structure 120 directly. A manufacturing method of the electronic package 10 according to an embodiment of

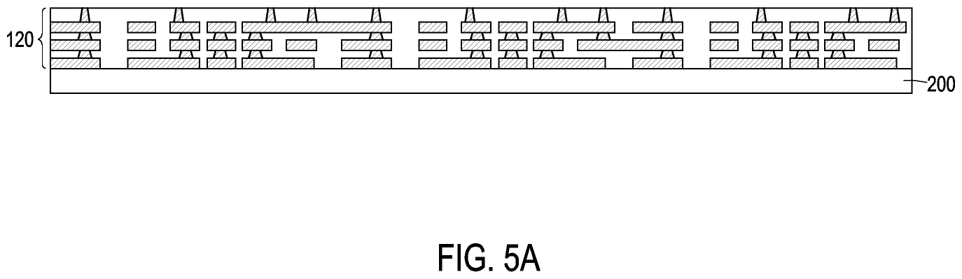

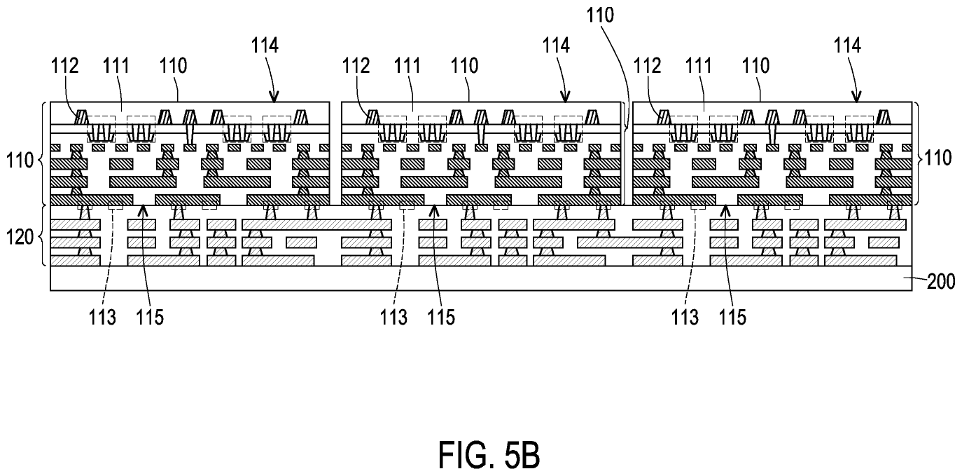

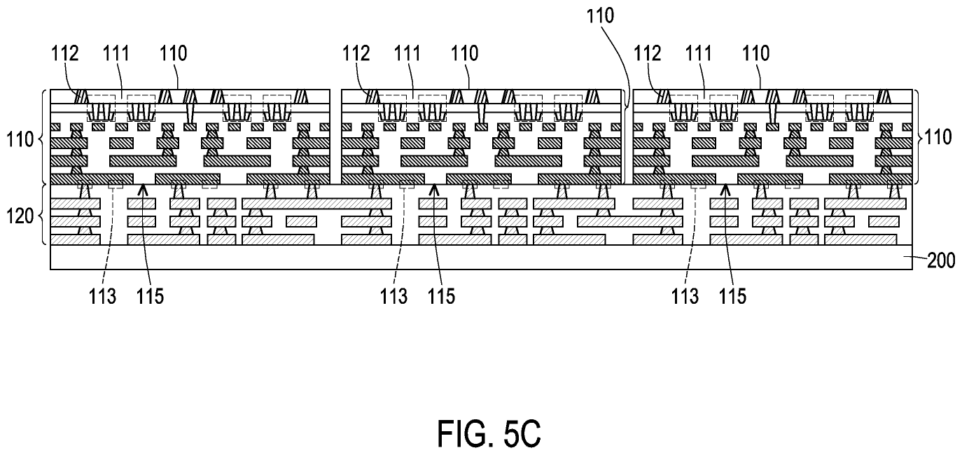

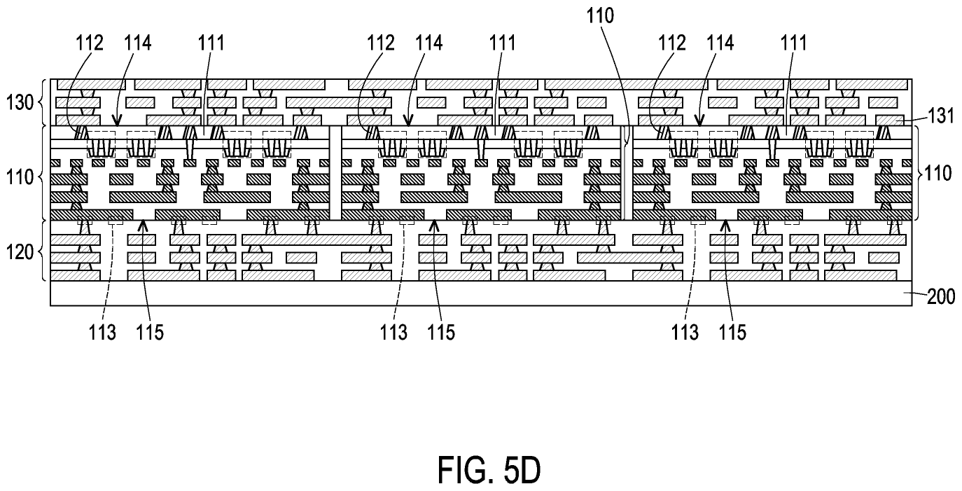

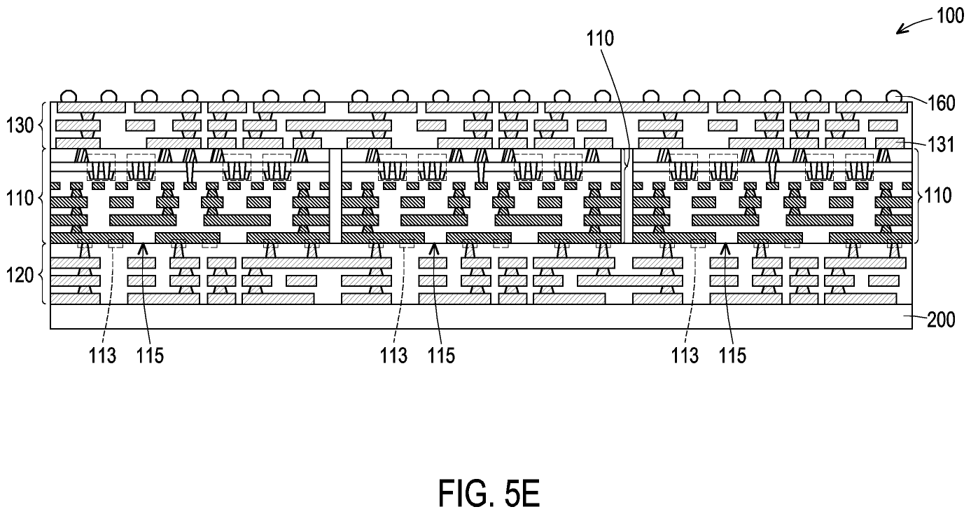

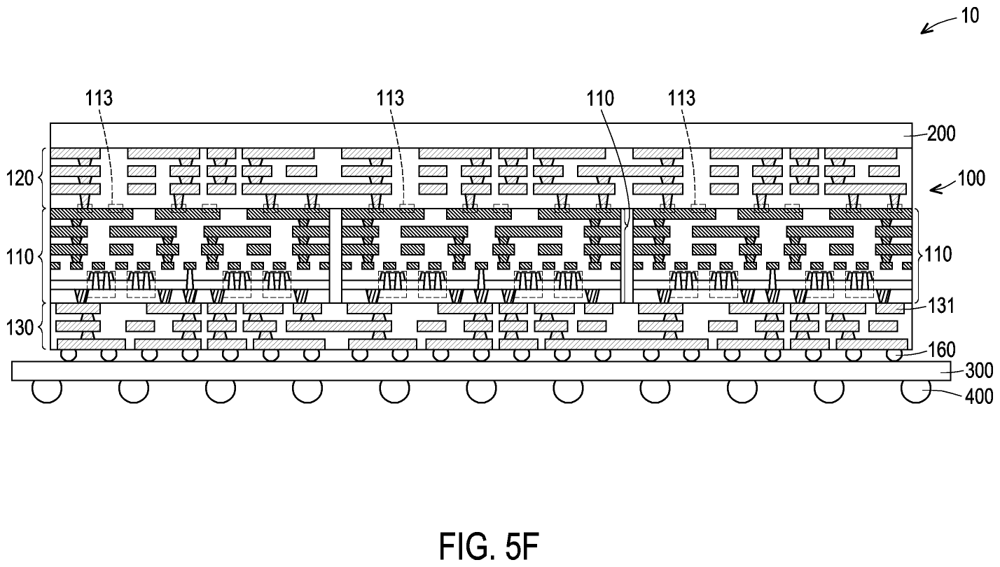

the disclosure will be described below with reference to FIGS. 5A to 5F, which may produce the electronic package 10 the same as in the embodiment of FIG. 2.

Referring to FIGS. 5A and 5B, the first redistribution wiring structure 120 is manufactured on the supportive carrying plate 200, and the multiple chips 110 are installed on the first redistribution wiring structure 120. The active surfaces 115 of the chips 110 are connected to the first redistribution wiring structure 120. Specifically, the chips 110 have the multiple chip pads 113. The chip pads 113 are disposed on the active surfaces 115, and the chip pads 113 are connected to the first redistribution wiring structure 120. Therefore, although the chips 110 are spatially disposed independently, the chips 110 may be electrically connected to each other through the first redistribution wiring structure 120, so that signals may be transmitted between the chips 110.

In this embodiment, each of the chips 110 further has a chip substrate 111 and the multiple buried power rails 112. The backside 114 of the chip 110 is a portion of the chip substrate 111 correspondingly, and the buried power rails 112 are disposed in the chip substrate 111. One of the chips 110 may be a central processing unit chip, a logic chip, a graphics processing chip, an input/output chip, a memory chip, a base band chip, a RF chip, or an integrated circuit chip with a specific function. In other words, the chips 110 may include a combination of the aforementioned chips of different functional types, so that the electronic package 10 in FIGS. 2 to 4 may be applied to chiplet packaging technology, which is similar to system in a packaging (SiP). Since the chips 110 may have different functions, the sizes of the chips 110 may be different. In some embodiments, the chips 110 may be a combination of a central processing unit chip and a logic chip, a combination of a central processing unit chip and an input/output chip, a combination of a graphics processing chip and a memory chip, a combination of a RF chip and a base band chip, or may also be a combination of two chips with the same function. In some embodiments, the chips 110 may be two or more, depending on the needs.

Referring to FIG. 5C, the chip substrates 111 of the chips 110 are thinned and planarized to expose the buried power rails 112. In this embodiment, chemical mechanical polishing (CMP) and dry/wet etching may be used for thinning and planarization. On the other hand, through this step, the problem that the multiple chips 110 have different thicknesses in some cases can be solved.

Referring to FIGS. 5D to 5E, the second redistribution wiring structure 130 is formed on the backside 114 of the chips 110. The second redistribution wiring structure 130 is directly connected to the buried power rails 112 exposed. In addition, the second redistribution wiring structure 130 further has the multiple power planes 131. The power planes 131 are disposed closely to the end of the backside 114 of the chips 110, and each of the power planes 131 is directly connected to at least one of the buried power rails 112. That is to say, the quantity of connections between each of the power planes 131 and the buried power rails 112 may be one or more, depending on the needs. In addition, the power planes 131 are directly connected to the buried power rails 112, so that each of the chips 110 is directly connected to the external power supply through the second redistribution wiring structure 130, thereby the issue that the manufacturing of the nano-through-silicon via with a high aspect ratio on the backside 114 of the chips 110 can be omitted. Finally, the multiple conductive bumps 160 are formed on the second redistribution wiring structure 130. At this point, the sub-package 100 is completed.

Referring to FIG. 5F, the conductive bumps 160 are connected to the wire carrying plate 300, and the multiple conductive balls 400 are connected to the wire carrying plate 300. At this point, the electronic package 10 is completed.

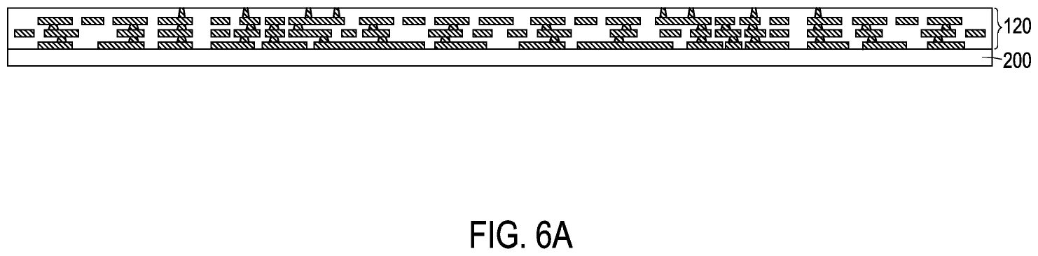

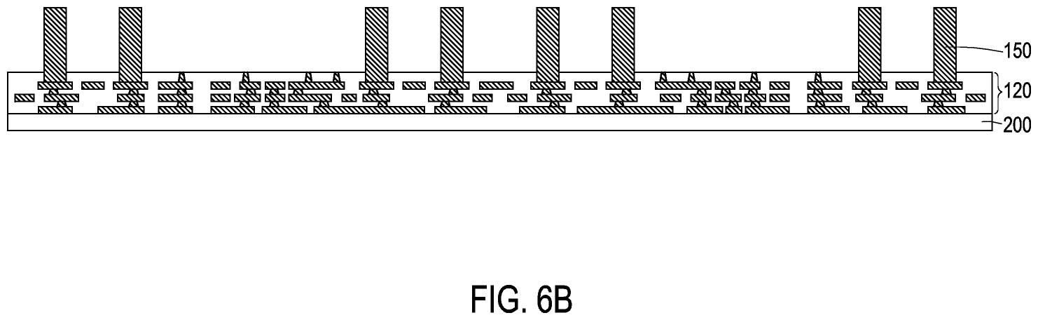

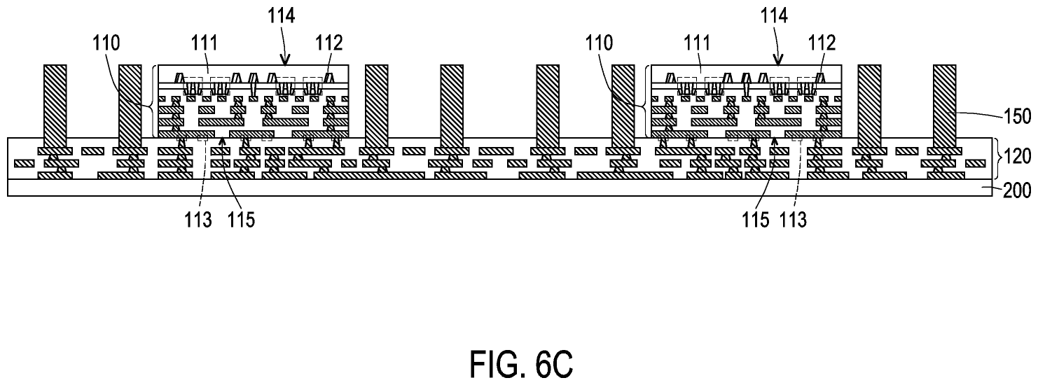

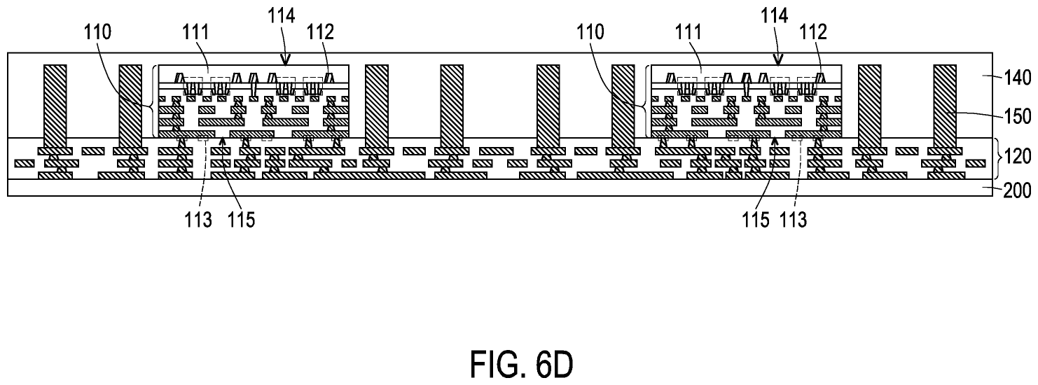

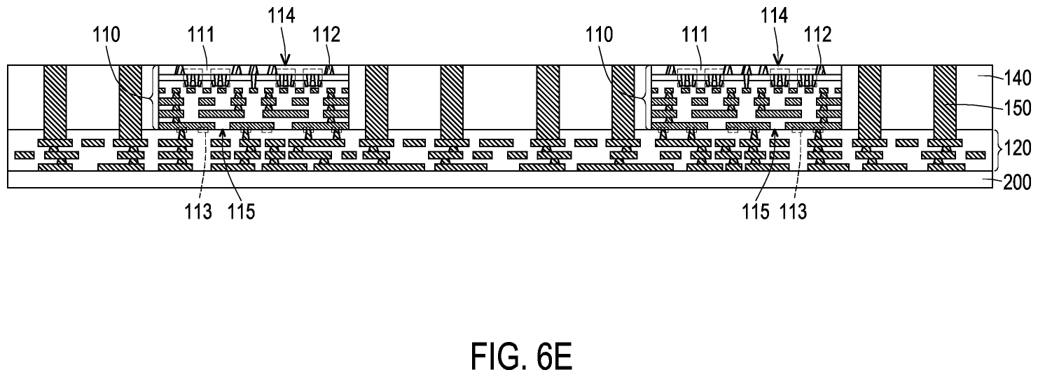

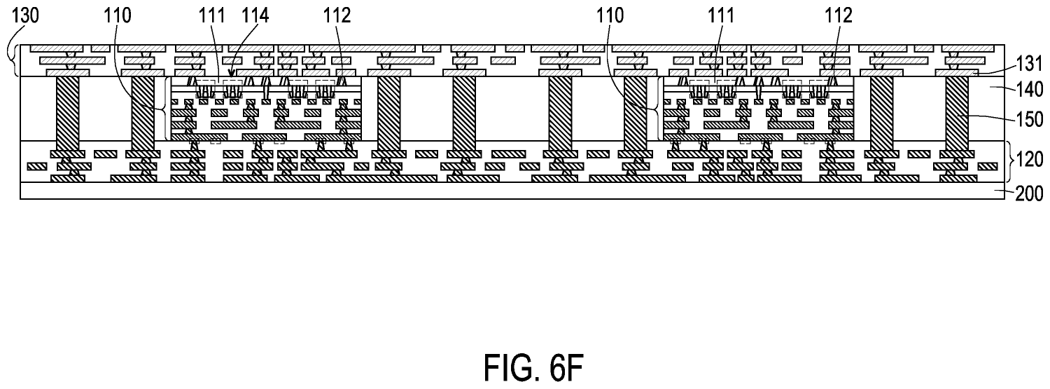

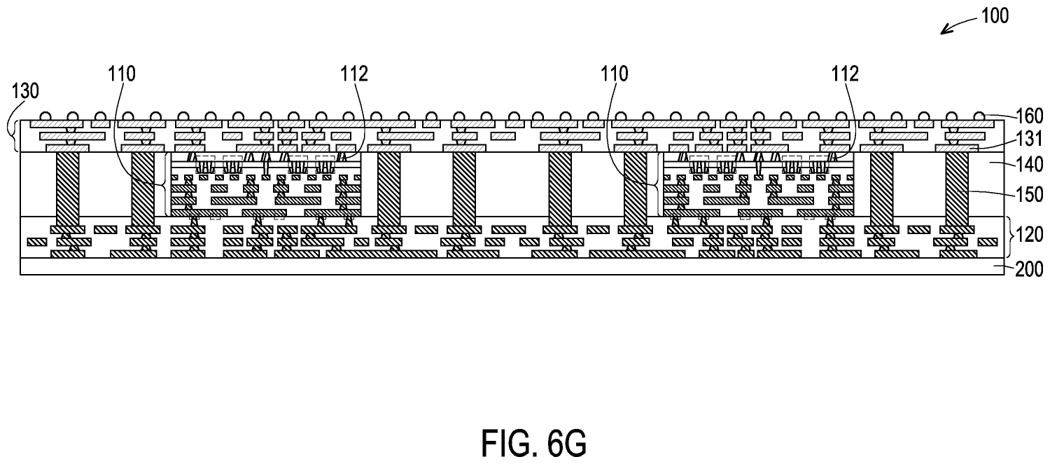

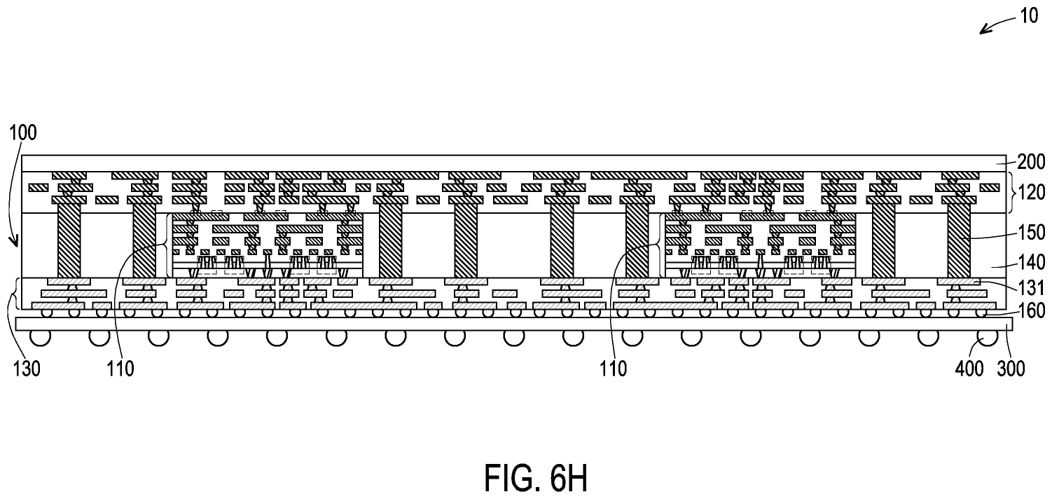

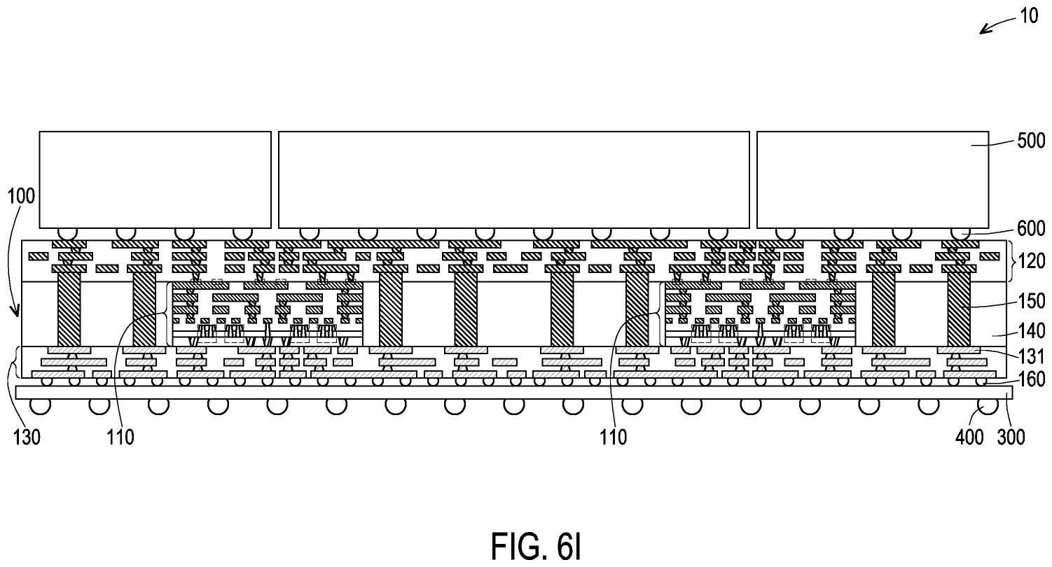

The manufacturing method of the electronic package 10 according to another embodiment of the disclosure will be described below with reference to FIGS. 6A to 6H, which may produce the electronic package 10 the same as in the embodiment of FIG. 3.

Referring to FIGS. 6A and 6B, the first redistribution wiring structure 120 is manufactured on the supportive carrying plate 200, and the plurality of conductive columns 150 are formed on the first redistribution wiring structure 120.

Referring to FIG. 6C, the multiple chips 110 are installed on the first redistribution wiring structure 120. The active surface 115 of the chips 110 are connected to the first redistribution wiring structure 120, and the chips 110 are disposed between two adjacent conductive columns 150. Specifically, the chips 110 have multiple chip pads 113. The chip pads 113 are disposed on the active surface 115, and the chip pads 113 are connected to the first redistribution wiring structure 120. Therefore, although the chips 110 are spatially disposed independently, the chips 110 may be electrically connected to each other through the first redistribution wiring structure 120, so that signals may be transmitted between the chips 110.

In this embodiment, each of the chips 110 further has a chip substrate 111 and the multiple buried power rails 112. The backside 114 of the chip 110 is a portion of the chip substrate 111 correspondingly, and the buried power rails 112 are disposed in the chip substrate 111.

Referring to FIG. 6D, the dielectric layer 140 is formed on the first redistribution wiring structure 120. The dielectric layer 140 covers the chips 110 and the conductive columns 150, and the dielectric layer 140 fills gaps between the chips 110.

Referring to FIG. 6E, the dielectric layer 140 is thinned and planarized to expose the buried power rails 112 and the conductive columns 150. In this embodiment, chemical-mechanical polishing (CMP) and dry/wet etching may be used for thinning and planarization. On the other hand, through this step, the problem that the multiple chips 110 have different thicknesses in some cases can be solved.

Referring to FIGS. 6F to 6G, the second redistribution wiring structure 130 is formed on the dielectric layer 140. The second redistribution wiring structure 130 is directly connected to the buried power rails 112 exposed and the conductive columns 150. In addition, the second redistribution wiring structure 130 further has the multiple power planes 131. The power planes 131 are disposed closely to the end of the backside 114 of the chips 110, and each of the power planes 131 is directly connected to at least one of the buried power rails 112. That is to say, the quantity of connections between each of the power planes 131 and the buried power rails 112 may be one or more, depending on the needs. In addition, the power planes 131 are directly connected to the buried power rails 112, so that each of the chips 110 is directly connected to the external power supply through the second redistribution wiring structure 130, thereby the issue that the manufacturing of the nano-through-silicon via with a high aspect ratio on the backside 114 of the chips 110 can be omitted. Finally, the multiple conductive bumps 160 are formed on the second redistribution wiring structure 130. At this point, the sub-package 100 is completed.

Referring to FIG. 6H, the conductive bumps 160 are connected to the wire carrying plate 300, and the multiple conductive balls 400 are connected to the wire carrying plate 300. At this point, the electronic package 10 is completed.

Please refer to FIG. 6I, which may produce the electronic package 10 the same as in the embodiment of FIG. 4. After completing the previous steps of FIGS. 6A to 6H, the supportive carrying plate 200 is removed and the multiple electronic components 500 are installed on the first redistribution wiring structure 120. The electronic components 500 may be electrically connected to the first redistribution wiring structure 120 through the plurality of conductive balls 600.

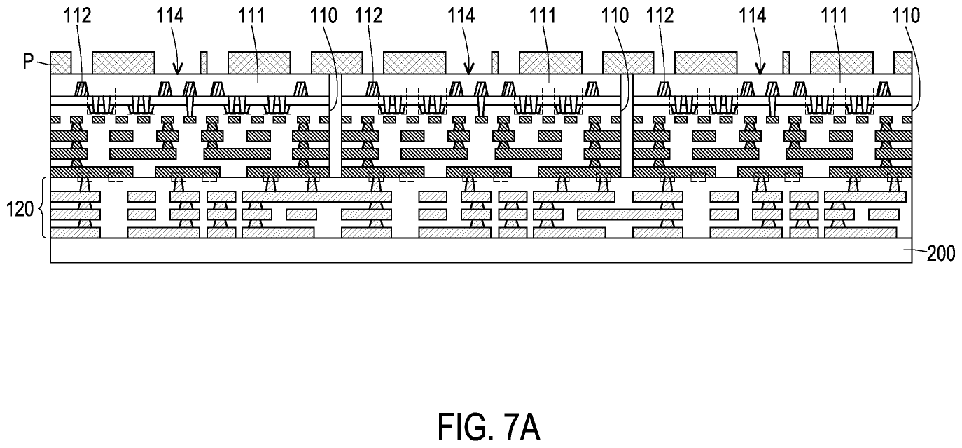

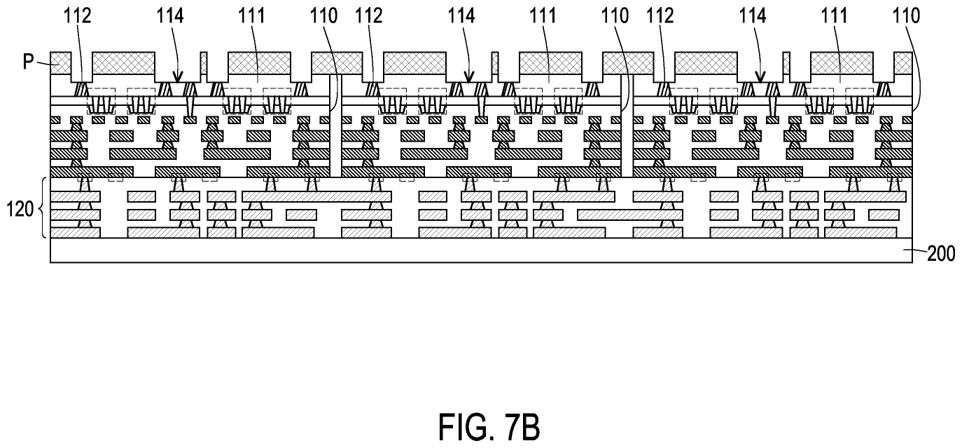

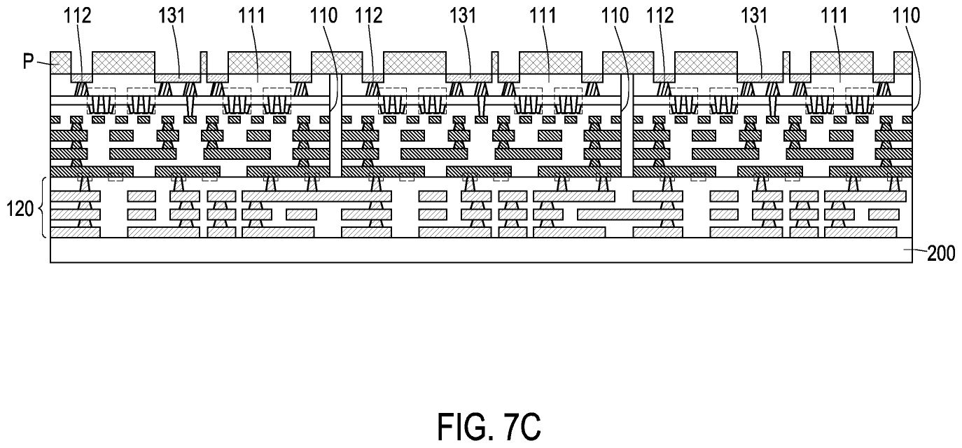

In another embodiment, the steps of FIGS. 5B to 5C may also be changed to the steps of FIGS. 7A to 7C, as described below.

Specifically, after the steps of FIG. 5A, referring to FIG. 7A, the step of forming the second redistribution wiring structure 130 on the backside 114 of the chips 110 further includes forming a patterning mask P on the backside 114 of the chips 110.

Referring to FIG. 7B, multiple portions of each of the chips 110 exposed by the patterning mask P are removed, and the buried power rail 112 are exposed.

Referring to FIG. 7C, the multiple power planes 131 are formed on the buried power rails 112 exposed. Each of the power planes 131 is directly connected to at least one of the buried power rails 112. In the step of removing the multiple portions of each of the chips 110 exposed by the patterning mask P, dry/wet etching may be used so that areas not covered by the patterning mask P are etched to the buried power rails 112 exposed. At this point, the exposure of the power rails 112 from the backside 114 of the chips 110 is completed.

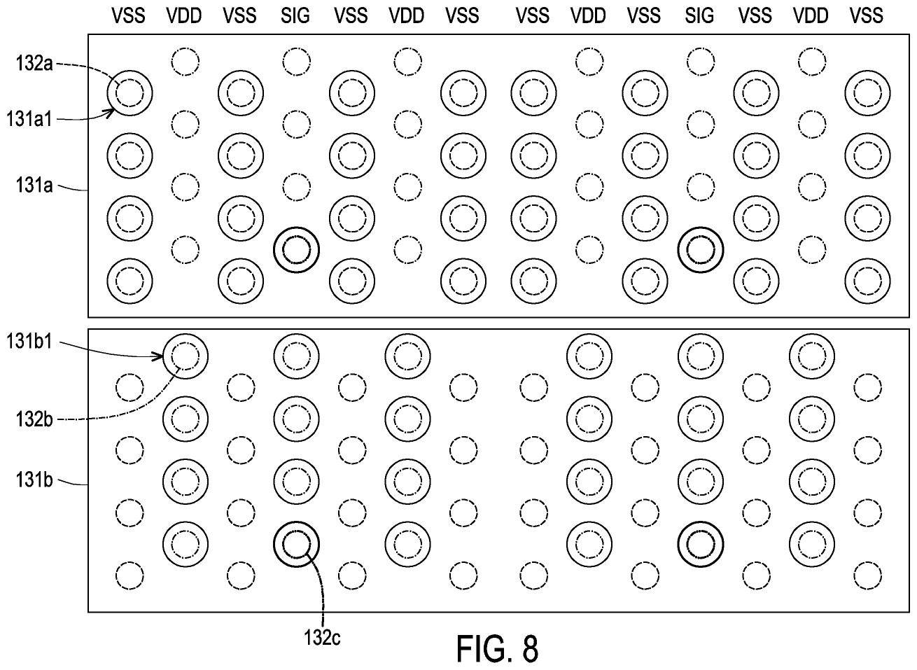

Please refer to FIGS. 2 and 8. In this embodiment, the power planes 131 of the second redistribution wiring structure 130 include a first power plane 131a and a second power plane 131b, and the first power plane 131a and the second power plane 131b are parallel to each other. The first power plane 131a has a plurality of first openings 131a1, the second power plane 131b has a plurality of second openings 131b1, and the first openings 131al and the second openings 131b1 do not overlap to each other. The second redistribution wiring structure 130 further includes a plurality of first redistribution conductive hole channels 132a, a plurality of second redistribution conductive hole channels 132b, and a plurality of third redistribution conductive hole channels 132c. The first redistribution conductive hole channels 132a pass through the first openings 131al and connect to the second power plane 131b, so as to electrically connect to the buried power rails 112 of the chips 110. The second redistribution conductive hole channels 132b pass through the second openings 131b1 and connect to the first power plane 131a, so as to electrically connect to the buried power rails 112 of the chips 110. These third redistribution conductive hole channels 132c pass through the first openings 131al and the second openings 131b1 and connect to the second redistribution wiring structure 130. In other words, the third redistribution conductive hole channels 132c do not connect to the first power plane 131a or the second power plane 131b. Specifically, in this embodiment, the first redistribution conductive hole channels 132a are, for example, connected to power terminals (VDD) of the chips 110, the second redistribution conductive hole channels 132b are, for example, connected to ground terminals (VSS) of the chips 110, and the third redistribution conductive hole channels 132c are, for example, connected to signal terminals (SIG) of the chips 110. Since the first redistribution conductive hole channels 132a, the second redistribution conductive hole channels 132b, and the third redistribution conductive hole channels 132c are not electrically connected to each other, mutual interference between signals can be reduced. In addition, the buried power rails 112 of the chips 110 are directly connected to the power planes 131 (for example, the first power plane 131a or the second power plane 131b) correspondingly, the electrically connected contact area between the chips 110 and the second redistribution wiring structure 130 may be increased, thereby power strips are increased, so as to improve the performance of the chip 110.

In summary, in the disclosure, the power planes of the second redistribution wiring structure are directly connected to the buried power rails of the multiple chips, so that the multiple chips of the electronic package can be directly connected to the external power supply through the second redistribution wiring structure, which facilitates reducing the circuit efficiency of the chips and improving the performance of the chips. In addition, through connecting the buried power rail of the chip directly to the second redistribution wiring structure, the process of manufacturing the nano-through-silicon via can be omitted, so as to reduce the production cost of the chip.

What is claimed is:

1. An electronic package, comprising:
a sub-package, comprising:
a plurality of chips, arranged on a plane, wherein each of the chips has a chip substrate, a plurality of buried power rails, and a plurality of chip pads, wherein the backside of the chip is a portion of the chip substrate correspondingly, the buried power rails are disposed penetratingly in the chip substrate, and the chip pads are disposed on active surfaces of the chips correspondingly;
a first redistribution wiring structure disposed on the active surfaces of the chips and electrically connected to the chip pads; and
a second redistribution wiring structure disposed on the backside of the chips and connected to the buried power rails, wherein the buried power rails of the chips are electrically connected to an external power supply via the second redistribution wiring structure.

2. The electronic package as claimed in claim 1, wherein the second redistribution wiring structure has a plurality of power planes, and each of the power planes is directly connected to at least one of the buried power rails.

3. The electronic package as claimed in claim 1, wherein the chips are electrically connected to each other via the first redistribution wiring structure.

4. The electronic package as claimed in claim 1, wherein the sub-package further comprises:
a dielectric layer covering the chips.

5. The electronic package as claimed in claim 4, wherein the sub-package further comprises:
a plurality of conductive columns, penetrating the dielectric layer, and connecting to the first redistribution wiring structure and the second redistribution wiring structure.

6. The electronic package as claimed in claim 1, further comprising:
a supportive carrying plate, stacked with the first redistribution wiring structure.

7. The electronic package as claimed in claim 1, further comprising:
a plurality of electronic components, installed on the first redistribution wiring structure.

8. The electronic package as claimed in claim 1, wherein the sub-package further comprises:
a plurality of conductive bumps, disposed on the second redistribution wiring structure, so as to connect to the external power supply.

9. The electronic package as claimed in claim 1, further comprising:
a wire carrying plate, wherein the sub-package is installed on the wire carrying plate.

10. A manufacturing method of an electronic package, comprising:
forming a first redistribution wiring structure on a supportive carrying plate;
installing a plurality of chips on the first redistribution wiring structure, wherein active surfaces of the chips are connected to the first redistribution wiring structure; and
forming a second redistribution wiring structure on backside of the chips, wherein the second redistribution wiring structure is connected to a plurality of buried power rails of the chips.

11. The manufacturing method of the electronic package as claimed in claim 10, wherein forming the second redistribution wiring structure on the backside of the chips further comprises:
thinning and planarizing the backside of the chips to expose the buried power rails; and
forming a plurality of power planes on the buried power rails exposed, wherein each of the power planes is directly connected to at least one of the buried power rails.

12. The manufacturing method of the electronic package as claimed in claim 10, wherein forming the second redistribution wiring structure on the backside of the chips further comprises:
forming a patterning mask on the backside of the chips;
removing a plurality of portions of each of the chips exposed by the patterning mask, so as to expose the buried power rails; and
forming a plurality of power planes on the buried power rails exposed, wherein each of the power planes is directly connected to at least one of the buried power rails.

13. The manufacturing method of the electronic package as claimed in claim 10, wherein the chips further have a plurality of chip pads disposed on the active surfaces of the chips, and the chip pads are electrically connected to the first redistribution wiring structure.

14. The manufacturing method of the electronic package as claimed in claim 10, further comprising:
forming a plurality of conductive columns on the first redistribution wiring structure after forming the first redistribution wiring structure on the supportive carrying plate.

15. The manufacturing method of the electronic package as claimed in claim 14, wherein providing the chips and connecting electrically to the first redistribution wiring structure further comprises:
disposing the chips between the conductive columns;
forming a dielectric layer on the first redistribution wiring structure, so as to cover the chips and the conductive columns, and fill gaps between the chips; and
thinning and planarizing the dielectric layer, so as to expose the conductive columns.

16. The manufacturing method of the electronic package as claimed in claim 15, wherein forming the second redistribution wiring structure on the backside of the chips further comprises:
forming the second redistribution wiring structure on the dielectric layer and connecting electrically to the conductive columns.

17. The manufacturing method of the electronic package as claimed in claim 15, further comprising:
installing a plurality of electronic components on the first redistribution wiring structure.

18. The manufacturing method of the electronic package as claimed in claim 10, further comprising:
forming a plurality of conductive bumps on the second redistribution wiring structure;
connecting the conductive bumps to a wire carrying plate; and
connecting a plurality of conductive balls to the wire carrying plate.
